(19) United States
(12) Patent Application Publication
(10) Pub. No.: US 2012/0175650 A1
(43) Pub. Date: Jul. 12, 2012

(54) ILLUMINATING DEVICE AND DISPLAY DEVICE

(75) Inventors: Akira Tomiyoshi, Osaka-shi (JP); Naoto Inoue, Osaka-shi (JP); Takeshi Masuda, Osaka-shi (JP); Yuhsaku Ajichi, Osaka-shi (JP)

(73) Assignee: SHARP KABUSHIKI KAISHA, Osaka-shi, Osaka (JP)

(21) Appl. No.: 13/497,098

(22) PCT Filed: May 11, 2010
(86) PCT No.: PCT/JP2010/057966

§ 371 Date: Mar. 20, 2012

(30) Foreign Application Priority Data
Oct. 9, 2009 (JP) 2009-235066

(51) Int. Cl. H01L 33/08

(52) U.S. Cl. 257/89; 257/E33.055

(57) ABSTRACT

An illuminating device (4) includes a light emitting diode substrate (8). A connector (20) is provided at a predetermined position on one end in the longitudinal direction of the light emitting diode substrate (8). Two light emitting diode substrates (8) are adjacent in an arrangement direction, and a plurality of light emitting diodes (18r), (18g), and (18b) included in light emitting diode units (19a) to (19h) in each of the two light emitting diode substrates (8) are provided so as to be symmetrical with respect to a point that is in the center of these two light emitting diode substrates (8).

### TECHNICAL FIELD

The present invention relates to an illuminating device used, e.g., in a backlight or the like, and a display device using the illuminating device.

### BACKGROUND ART

In recent years, e.g., a liquid crystal display device has been widely used for a liquid crystal television, a monitor, a portable telephone, etc. as a flat panel display having features such as a smaller thickness and a lighter weight compared to a conventional Braun tube. Such a liquid crystal display device includes an illuminating device and a liquid crystal panel. The illuminating device emits light and the liquid crystal panel displays a desired image by serving as a shutter with respect to light from a light source provided in the illuminating device.

The above illuminating device has been provided as an edge-light type or a direct type in which a linear light source composed of a cold-cathode fluorescent tube or a hot-cathode fluorescent tube is located on the side or underside of the liquid crystal panel. However, the cold-cathode fluorescent tube etc. contains mercury and is not easily recyclable when they are discarded. Therefore, an illuminating device using a mercury-free light emitting diode (LED) as a light source has been proposed.

A conventional illuminating device, as described in, e.g., Patent Document 1, includes a light emitting block that includes a wiring board, a plurality of light emitting diodes mounted on the wiring board and arranged in a line, and a connector to which electric wires such as a power line for supplying electric power to the light emitting diodes are connected. In the conventional illuminating device, a plurality of the light emitting blocks are placed in both longitudinal and lateral directions, and the electric wires are connected to the connectors, so that images with high brightness can be displayed on a large liquid crystal panel.

### PRIOR ART DOCUMENTS

### Patent Documents

Patent Document 1: JP 2005-353498 A

### DISCLOSURE OF INVENTION

### Problem to be Solved by the Invention

However, in the above conventional illuminating device, when the number of light emitting diodes to be mounted is increased with an increase in the screen size or brightness of the liquid crystal display device, there has been a problem that the number of types of the light emitting blocks (light emitting diode substrates) is also increased.

Specifically, in the conventional illuminating device, the connector that is connected to the electric wires is provided on the end of each of the light emitting blocks in the longitudinal direction so that the connectors of two adjacent light emitting blocks face each other. Therefore, when the number of light emitting diodes to be mounted is increased, the conventional illuminating device requires at least two types of the light emitting blocks.

With the foregoing in mind, it is an object of the present invention to provide an illuminating device that can be configured by one type of light emitting diode substrate even if the number of light emitting diodes to be mounted is increased, and a display device using the illuminating device.

### Means for Solving Problem

To achieve the above object, an illuminating device of the present invention includes the following: a light emitting diode unit including a plurality of light emitting diodes with colors that can be mixed into white color; and a light emitting diode substrate including at least one pair of the light emitting diode unit. A plurality of the light emitting diode substrates are placed along a predetermined arrangement direction. Each of the plurality of the light emitting diode substrates has a connector at a predetermined position to supply electric power to the plurality of the light emitting diodes mounted on the light emitting diode substrate. In the plurality of the light emitting diode substrates, two light emitting diode substrates are adjacent in the arrangement direction, and the plurality of the light emitting diodes included in the light emitting diode unit in each of the two light emitting diode substrates are provided so as to be symmetrical with respect to a point that is in the center of the two light emitting diode substrates.

In the illuminating device having the above configuration, the connector is provided at the predetermined position of the light emitting diode substrate. Moreover, two light emitting diode substrates are adjacent in the arrangement direction, and the plurality of the light emitting diodes included in the light emitting diode unit in each of the two light emitting diode substrates are provided so as to be symmetrical with respect to the point that is in the center of the two light emitting diode substrates. Thus, the two light emitting diode substrates in the arrangement direction can be placed while they are rotated at 180 degrees to each other. Consequently, unlike the conventional example, the illuminating device can be configured by one type of light emitting diode substrate even if the number of light emitting diodes to be mounted is increased.

In the above illuminating device, the light emitting diode unit may include a red light emitting diode, a green light emitting diode, and a blue light emitting diode that emit red light, green light, and blue light, respectively, as the plurality of the light emitting diodes.

In this case, the illuminating device with excellent light emission quality can be easily provided.

In the above illuminating device, the light emitting diode unit may include a red light emitting diode, a green light emitting diode, a blue light emitting diode, and a white light emitting diode that emit red light, green light, blue light, and white light, respectively, as the plurality of the light emitting diodes.

In this case, the illuminating device with high brightness can be easily provided.

In the above illuminating device, the light emitting diode unit may include a red light emitting diode, a green light emitting diode, and a blue light emitting diode that emit red light, green light, and blue light, respectively, as the plurality of the light emitting diodes, and also may include two or more light emitting diodes with a predetermined color selected from the red, green, and blue light emitting diodes.

In this case, the illuminating device with high brightness and excellent light emission quality can be easily provided.

A display device of the present invention includes a display portion. The display portion is irradiated with light from any one of the above illuminating devices.

In the display device having the above configuration, the display portion is the illuminating device that can be configured by one type of light emitting diode substrate even if the number of light emitting diodes to be mounted is increased. Therefore, the display device with high brightness and a simple structure can be easily provided.

### Effects of the Invention

The present invention can provide an illuminating device that can be configured by one type of light emitting diode substrate even if the number of light emitting diodes to be mounted is increased, and a display device using the illuminating device.

### BRIEF DESCRIPTION OF DRAWINGS

FIG. 1 is an exploded perspective view of a liquid crystal display device using an illuminating device according to Embodiment 1 of the present invention.

FIG. 2 is an exploded perspective view of the illuminating device.

FIG. 3 is a diagram for explaining the main configuration of the liquid crystal panel shown in FIG. 1.

FIG. 4 is a plan view showing the main configuration of the illuminating device.

FIG. 5 is a diagram for explaining the configuration of a light emitting diode substrate shown in FIG. 4.

FIG. 6 is a diagram for explaining the configuration of a light emitting diode substrate in an illuminating device according to Embodiment 2 of the present invention.

FIG. 7 is a diagram for explaining the configuration of a light emitting diode substrate in an illuminating device according to Embodiment 3 of the present invention.

FIG. 8 is a diagram for explaining the configuration of a light emitting diode substrate in an illuminating device according to Embodiment 4 of the present invention.

FIG. 9 is a diagram for explaining the configuration of a light emitting diode substrate in an illuminating device according to Embodiment 5 of the present invention.

FIG. 10 is an exploded perspective view of an illuminating device according to Embodiment 6 of the present invention.

FIG. 11 is a plan view showing the main configuration of the illuminating device shown in FIG. 10.

FIG. 12 is a diagram for explaining the configuration of a light emitting diode substrate shown in FIG. 11.

FIG. 13 is a diagram for explaining the configuration of a light emitting diode substrate in an illuminating device according to Embodiment 7 of the present invention.

FIG. 14 is a diagram for explaining the configuration of a light emitting diode substrate in an illuminating device according to Embodiment 8 of the present invention.

### DESCRIPTION OF THE INVENTION

Hereinafter, preferred embodiments of an illuminating device and a display device of the present invention will be described with reference to the drawings. In the following description, the present invention is applied to a transmission-type liquid crystal display device. The size and size ratio of each of the constituent members in the drawings do not exactly reflect those of the actual constituent members.

### Embodiment 1

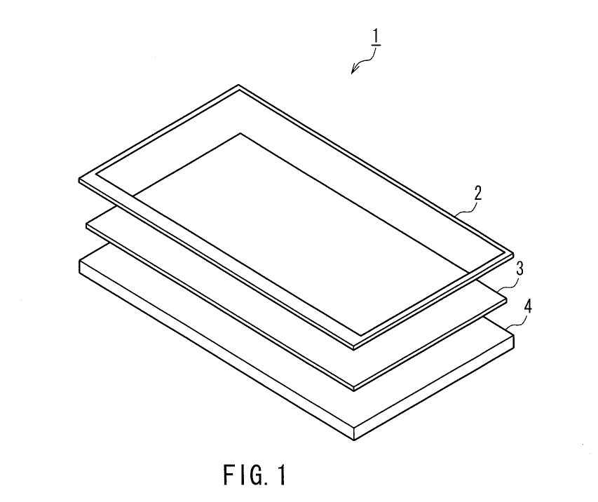

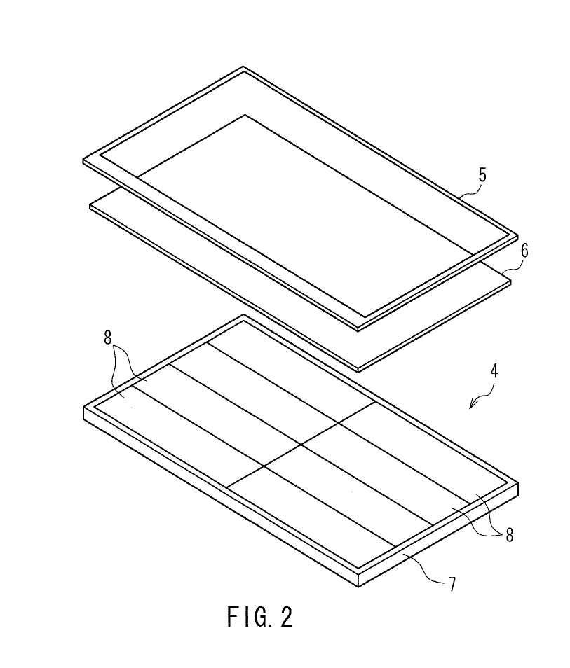

FIG. 1 is an exploded perspective view of a liquid crystal display device using an illuminating device according to Embodiment 1 of the present invention. FIG. 2 is an exploded perspective view of the illuminating device. In FIG. 1, a liquid crystal display device 1 of this embodiment includes a front frame 2, a liquid crystal panel 3, and an illuminating device 4 of the present invention. The liquid crystal panel 3 and the illuminating device 4 are placed in sequence behind the front frame 2. The front frame 2 is configured to surround a display surface of the liquid crystal panel 3. The liquid crystal panel 3 includes a transmission-type liquid crystal display element that has a liquid crystal layer and a pair of polarizing plates sandwiching the liquid crystal layer (not shown). Moreover, the liquid crystal panel 3 constitutes a display portion that is irradiated with planar light (illumination light) from the illuminating device 4. In this embodiment, the liquid crystal panel 3 and the illuminating device 4 are integrated into the transmission-type liquid crystal display device 1.

Referring also to FIG. 2, the illuminating device 4 includes a frame 5, an optical sheet 6, and a chassis 7. The frame 5 is configured to surround a light emitting surface of the illuminating device 4. The optical sheet 6 and the chassis 7 are placed in sequence behind the frame 5. The chassis 7 houses light emitting diode substrates (abbreviated as “LED substrates” in the following) 8 on which light emitting diodes serving as light sources are mounted. The optical sheet 6 includes known optical sheet materials such as a polarizing sheet, a prism (condensing) sheet, and a diffusing sheet as needed. The optical sheet 6 is used, e.g., to appropriately increase the brightness of the illumination light from the illuminating device 4, thereby improving the display performance of the liquid crystal panel 3.

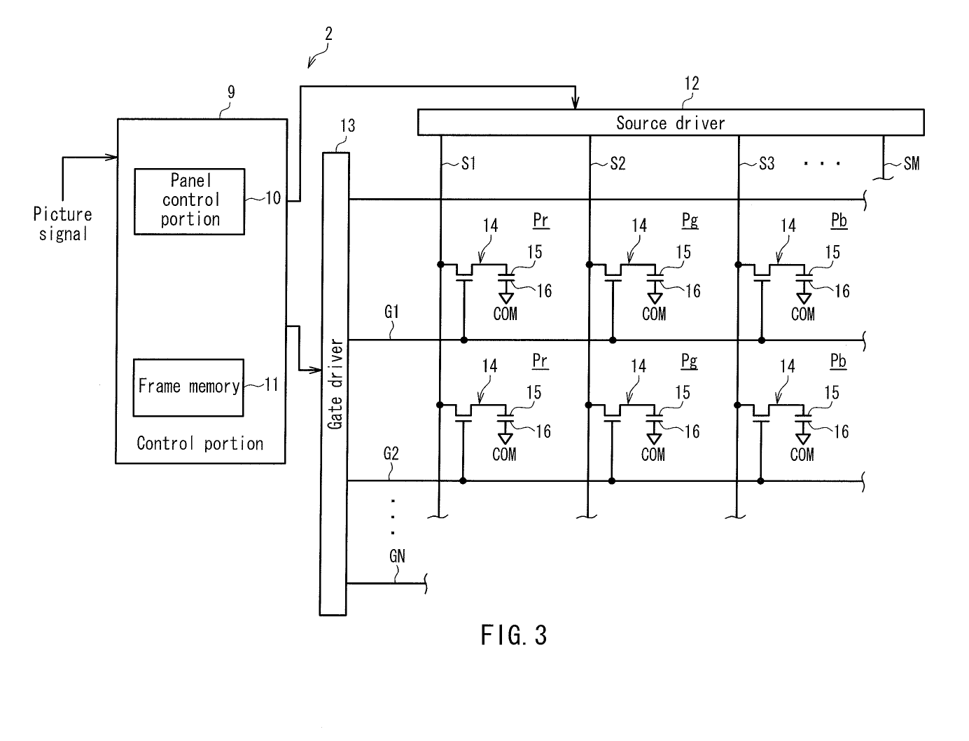

Hereinafter, the liquid crystal panel 3 will be described in detail with reference to FIG. 3.

FIG. 3 is a diagram for explaining the main configuration of the liquid crystal panel shown in FIG. 1.

In FIG. 3, a control portion 9 receives a picture signal from the outside of the liquid crystal display device 1 via a signal source (not shown) such as a television (receiver) or a personal computer. The control portion 9 includes a panel control portion 10 and a frame memory 11. The panel control portion 10 uses the input picture signal to drive and control a plurality of pixels provided in the liquid crystal panel 3 pixel by pixel. The frame memory 11 is capable of storing display data for each frame contained in the picture signal. The panel control portion 10 generates instruction signals for a source driver 12 and a gate driver 13 based on the picture signal, respectively.

The source driver 12 and the gate driver 13 are drive circuits for driving the plurality of pixels of the liquid crystal panel 3 pixel by pixel. A plurality of signal lines S1 to SM (M is an integer of not less than 2) and a plurality of control lines G1 to GN (N is an integer of not less than 2) are connected to the source driver 12 and the gate driver 13, respectively. The signal lines S1 to SM and the control lines G1 to GN are arranged in a matrix with areas left between them, and the plurality of pixels are formed in the individual areas. These pixels include red, green, and blue pixels Pr, Pg, and Pb. The red, green, and blue pixels Pr, Pg, and Pb are sequentially arranged, e.g., in this order in parallel with the control lines G1 to GN.

Switching elements 14 are provided in each of the pixels, and gates of the switching elements 14 are connected to the control lines G1 to GN. On the other hand, sources of the switching elements 14 are connected to the signal lines S1 to SM. Moreover, drains of the switching elements 14 are connected to pixel electrodes 15 that are provided in each of the pixels. Further, common electrodes 16 are provided in each of the pixels and configured to face the pixel electrodes 15 with the liquid crystal layer of the liquid crystal panel 3 interposed between them. Based on the instruction signal from the panel control portion 10, the gate driver 13 successively outputs gate signals to the control lines G1 to GN so as to bring the gates of the corresponding switching elements 14 into the on state. Based on the instruction signal from the panel control portion 10, the source driver 12 outputs voltage signals (gradation voltages) in accordance with the brightness (gradation) of the display image (picture signal) to the corresponding signal lines S1 to SM. Thus, the transmittance of light through the liquid crystal layer of the liquid crystal panel 3 varies from pixel to pixel, so that a display image is formed on the display surface by the illumination light from the light emitting surface of the illuminating device 4.

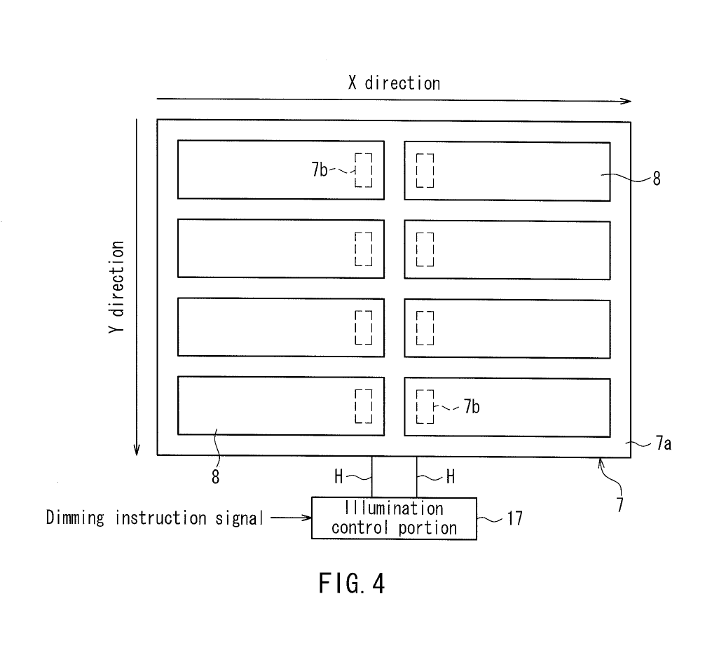

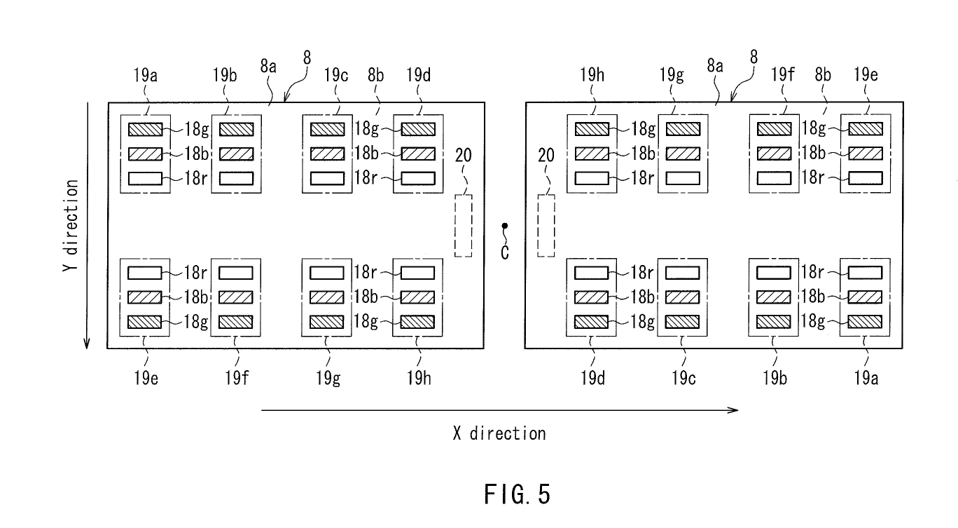

Next, the illuminating device 4 of this embodiment will be described in detail with reference to FIGS. 4 and 5.

FIG. 4 is a plan view showing the main configuration of the illuminating device. FIG. 5 is a diagram for explaining the configuration of a light emitting diode substrate shown in FIG. 4.

As shown in FIG. 4, in the illuminating device 4, a total of eight LED substrates 8 is housed in the chassis 7. Specifically, the LED substrates 8 are housed in a case 7a of the chassis 7 with the longitudinal direction parallel to the X direction. In the case 7a, the LED substrates 8 are arranged in two columns and four rows in the X direction and the Y direction, respectively. Connectors (as will be described later) of the LED substrates 8 are electrically connected to electric wires H that are laid through holes 7b formed in the case 7a of the chassis 7. As shown in FIG. 4, each of two electric wires H is appropriately connected to the connectors of the LED substrates 8 via four holes 7b provided along the Y direction. The two electric wires H are connected to an illumination control portion 17.

In the illuminating device 4, the illumination control portion 17 controls the lighting and driving of a plurality of light emitting diodes (FIG. 5) mounted on the LED substrates 8, e.g., using PWM dimming. Specifically, the illumination control portion 17 is configured to receive a dimming instruction signal from a remote controller (not shown) or the like included in the liquid crystal display device 1. The illumination control portion 17 changes the power supply to the light emitting diodes based on the input dimming instruction signal, and thus can appropriately adjust the brightness and chromaticity of illumination light, with which the liquid crystal panel 3 is irradiated.

As shown in FIG. 5, each of the LED substrates 8 includes eight light emitting diode units 19a, 19b, 19c, 19d, 19e, 19f, 19g, and 19h. Each of the light emitting diode units 19a to 19h includes a red light emitting diode 18r (shown without hatching) that emits red (R) light, a green light emitting diode 18g (shown with upper left to lower right hatching) that emits green (G) light, and a blue light emitting diode 18b (shown with upper right to lower left hatching) that emits blue (B) light. In the following description, the light emitting diodes 18r, 18g, and 18b are collectively called the light emitting diodes 18.

In the illuminating device 4 of this embodiment, as shown in FIG. 5, two LED substrates 8 are adjacent in the X direction, and the RGB light emitting diodes 18 included in the light emitting diode units 19a to 19h in each of the two adjacent LED substrates 8 are provided so as to be symmetrical with respect to a point C that is in the center of these two LED substrates 8. In the LED substrate 8 on the left side of FIG. 5, the light emitting diodes 18g, 18b, and 18r in each of the light emitting diode units 19a to 19d are mounted in the indicated order along the Y direction on a mounting surface 8a of the LED substrate 8. Moreover, in this left LED substrate 8, the light emitting diodes 18r, 18b, and 18g in each of the light emitting diode units 19e to 19h are mounted in the indicated order along the Y direction on the mounting surface 8a of the LED substrate 8.

On the other hand, in the LED substrate 8 on the right side of FIG. 5, the light emitting diodes 18g, 18b, and 18r in each of the light emitting diode units 19h to 19e are mounted in the indicated order along the Y direction on a mounting surface 8a of the LED substrate 8. Moreover, in this right LED substrate 8, the light emitting diodes 18r, 18b, and 18g in each of the light emitting diode units 19d to 19a are mounted in the indicated order along the Y direction on the mounting surface 8a of the LED substrate 8.

In each of the LED substrates 8, a connector 20 is provided on a back surface 8b of the LED substrate 8 that is on the other side of the mounting surface 8a, and located at a predetermined position on one end in the longitudinal direction of the LED substrate 8. This connector 20 serves to supply electric power to the light emitting diodes 18 mounted on the LED substrate 8 and is electrically connected to the electric wire H.

In other words, all the eight LED substrates 8 used in the illuminating device 4 of this embodiment have the same configuration and are housed in the case 7a of the chassis 7 while two adjacent LED substrates 8 in the X direction are rotated at 180 degrees.

In the illuminating device 4, the number of the LED substrates 8 to be placed, and the number, type, size, etc. of the light emitting diodes 18 are appropriately selected in accordance with the size of the liquid crystal panel 3 and the display performance such as brightness and display quality required in this liquid crystal panel 3.

In the illuminating device 4 having the above configuration of this embodiment, the connector 20 is provided at the predetermined position on one end in the longitudinal direction of each of the LED substrates (light emitting diode substrates) 8. Moreover, in the illuminating device 4 of this embodiment, two LED substrates 8 are adjacent in the X direction (arrangement direction), and the RGB light emitting diodes 18 included in the light emitting diode units 19a to 19h in each of the two adjacent LED substrates 8 are provided so as to be symmetrical with respect to the point C that is in the center of these two LED substrates 8. Thus, in the illuminating device 4 of this embodiment, the two adjacent LED substrates 8 in the X direction can be placed while they are rotated at 180 degrees to each other. Consequently, unlike the conventional example, the illuminating device 4 of this embodiment can be configured by one type of the LED substrate 8 even if the number of the light emitting diodes 18 to be mounted is increased.

In the illuminating device 4 of this embodiment, all the eight LED substrates 8 are the same, and the color arrays of the RGB light emitting diodes 18 in all the LED substrates 8 are the same. That is, in the illuminating device 4 of this embodiment, two LED substrates 8 are adjacent in the X direction, and the RGB light emitting diodes 18 in each of the two adjacent LED substrates 8 are provided so as to be symmetrical with respect to the point C that is in the center of these two LED substrates 8. Moreover, the color arrays of the RGB light emitting diodes 18 in two adjacent LED substrates 8 in the Y direction are also the same. Consequently, in the illuminating device 4 of this embodiment, the colors of the RGB light emitting diodes 18 are regularly arranged over the entire surface, and thus color unevenness can be easily improved.

In this embodiment, as described above, the display portion is the illuminating device 4 that can be configured by one type of the light emitting diode substrate 8 even if the number of the light emitting diodes 18 to be mounted is increased. Therefore, the liquid crystal display device 1 with high brightness and a simple structure can be easily provided.

### Embodiment 2

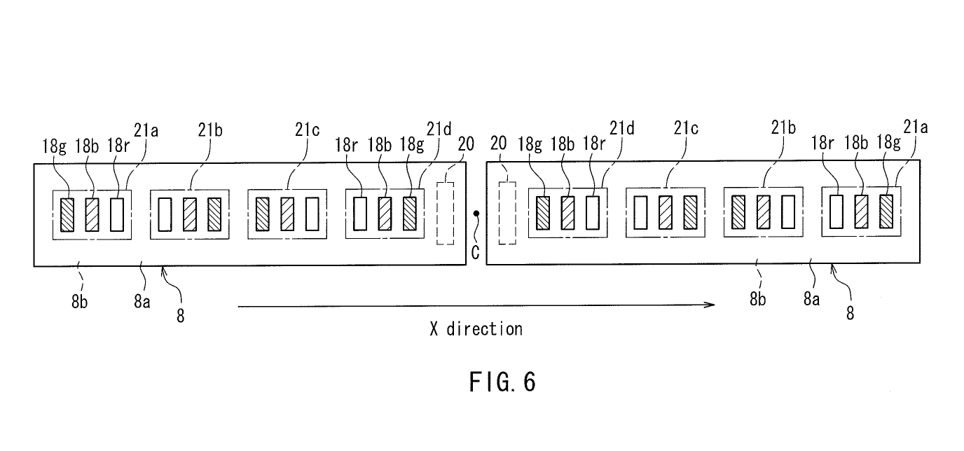

FIG. 6 is a diagram for explaining the configuration of a light emitting diode substrate in an illuminating device according to Embodiment 2 of the present invention. In FIG. 6, this embodiment mainly differs from Embodiment 1 in that the RGB light emitting diodes included in the light emitting diode units are mounted along the X direction on each of the LED substrates. The same components as those in Embodiment 1 are denoted by the same reference numerals, and the explanation will not repeated.

As shown in FIG. 6, each of the light emitting diode substrates (LED substrates) 8 of this embodiment includes four light emitting diode units 21a, 21b, 21c, and 21d. Each of the light emitting diode units 21a to 21d includes the RGB light emitting diodes 18.

In the illuminating device 4 of this embodiment, as shown in FIG. 6, two LED substrates 8 are adjacent in the X direction, and the RGB light emitting diodes 18 included in the light emitting diode units 21a to 21d in each of the two adjacent LED substrates 8 are provided so as to be symmetrical with respect to a point C that is in the center of these two LED substrates 8. In the LED substrate 8 on the left side of FIG. 6, the light emitting diodes 18g, 18b, and 18r in the light emitting diode unit 21a are mounted in the indicated order along the X direction on a mounting surface 8a of the LED substrate 8. The light emitting diodes 18r, 18b, and 18g in the light emitting diode unit 21b are mounted in the indicated order along the X direction on the mounting surface 8a of the LED substrate 8. The light emitting diodes 18g, 18b, and 18r in the light emitting diode unit 21c are mounted in the indicated order along the X direction on the mounting surface 8a of the LED substrate 8. The light emitting diodes 18r, 18b, and 18g in the light emitting diode unit 21d are mounted in the indicated order along the X direction on the mounting surface 8a of the LED substrate 8.

On the other hand, in the LED substrate 8 on the right side of FIG. 6, the light emitting diodes 18g, 18b, and 18r in the light emitting diode unit 21d are mounted in the indicated order along the X direction on a mounting surface 8a of the LED substrate 8. The light emitting diodes 18r, 18b, and 18g in the light emitting diode unit 21c are mounted in the indicated order along the X direction on the mounting surface 8a of the LED substrate 8. The light emitting diodes 18g, 18b, and 18r in the light emitting diode unit 21b are mounted in the indicated order along the X direction on the mounting surface 8a of the LED substrate 8. The light emitting diodes 18r, 18b, and 18g in the light emitting diode unit 21a are mounted in the indicated order along the X direction on the mounting surface 8a of the LED substrate 8.

In each of the LED substrates 8 on the left side and right side of FIG. 6, the connector 20 is electrically connected to the electric wire H.

In other words, all the eight LED substrates 8 used in the illuminating device 4 of this embodiment have the same configuration and are housed in the case 7a of the chassis 7 while two adjacent LED substrates 8 in the X direction are rotated at 180 degrees.

With the above configuration, this embodiment can have the same function and effect as those of Embodiment 1.

### Embodiment 3

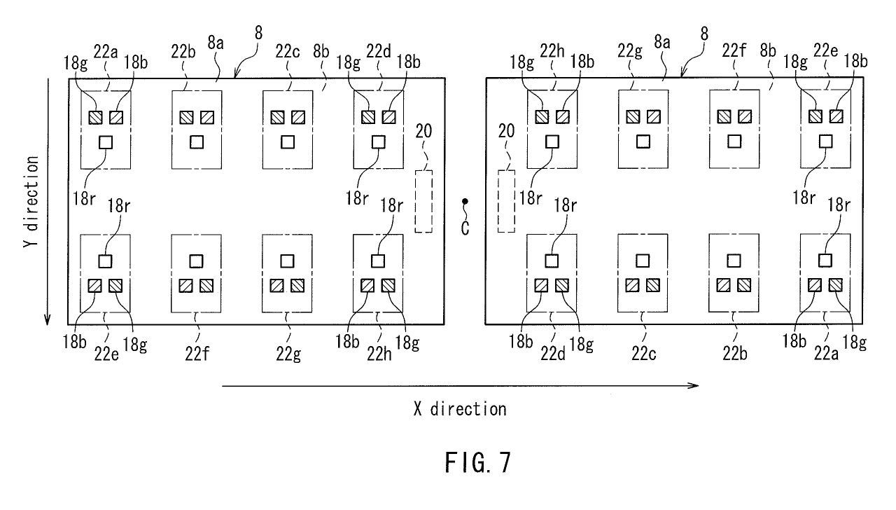

FIG. 7 is a diagram for explaining the configuration of a light emitting diode substrate in an illuminating device according to Embodiment 3 of the present invention. In FIG. 7, this embodiment mainly differs from Embodiment 1 in that the RGB light emitting diodes included in the light emitting diode units are mounted in a triangular shape on each of the LED substrates. The same components as those in Embodiment 1 are denoted by the same reference numerals, and the explanation will not repeated.

As shown in FIG. 7, each of the light emitting diode substrates (LED substrates) 8 of this embodiment includes eight light emitting diode units 22a, 22b, 22c, 22d, 22e, 22f, 22g, and 22h. Each of the light emitting diode units 22a to 22h includes the RGB light emitting diodes 18.

In the illuminating device 4 of this embodiment, as shown in FIG. 7, two LED substrates 8 are adjacent in the X direction, and the RGB light emitting diodes 18 included in the light emitting diode units 22a to 22h in each of the two adjacent LED substrates 8 are provided so as to be symmetrical with respect to a point C that is in the center of these two LED substrates 8.

In the LED substrate 8 on the left side of FIG. 7, the RGB light emitting diodes 18 in each of the light emitting diode units 22a to 22d are placed in a triangular shape. Specifically, the light emitting diode 18r is placed at the position of one vertex of the triangular shape, and the light emitting diodes 18g, 18b are placed at the positions of the other two vertices of the triangular shape on the upper side of FIG. 7 with respect to the light emitting diode 18r. Moreover, in this left LED substrate 8, the RGB light emitting diodes 18 in each of the light emitting diode units 22e to 22h are placed in a triangular shape. Specifically, the light emitting diode 18r is placed at the position of one vertex of the triangular shape, and the light emitting diodes 18b, 18g are placed at the positions of the other two vertices of the triangular shape on the lower side of FIG. 7 with respect to the light emitting diode 18r.

On the other hand, in the LED substrate 8 on the right side of FIG. 7, the RGB light emitting diodes 18 in each of the light emitting diode units 22h to 22e are placed in a triangular shape. Specifically, the light emitting diode 18r is placed at the position of one vertex of the triangular shape, and the light emitting diodes 18g, 18b are placed at the positions of the other two vertices of the triangular shape on the upper side of FIG. 7 with respect to the light emitting diode 18r. Moreover, in this right LED substrate 8, the RGB light emitting diodes 18 in each of the light emitting diode units 22d to 22a are placed in a triangular shape. Specifically, the light emitting diode 18r is placed at the position of one vertex of the triangular shape, and the light emitting diodes 18b, 18g are placed at the positions of the other two vertices of the triangular shape on the lower side of FIG. 7 with respect to the light emitting diode 18r.

In each of the LED substrates 8 on the left side and right side of FIG. 7, the connector 20 is electrically connected to the electric wire H.

In other words, similarly to Embodiment 1, all the eight LED substrates 8 used in the illuminating device 4 of this embodiment have the same configuration and are housed in the case 7a of the chassis 7 while two adjacent LED substrates 8 in the X direction are rotated at 180 degrees.

With the above configuration, this embodiment can have the same function and effect as those of Embodiment 1.

### Embodiment 4

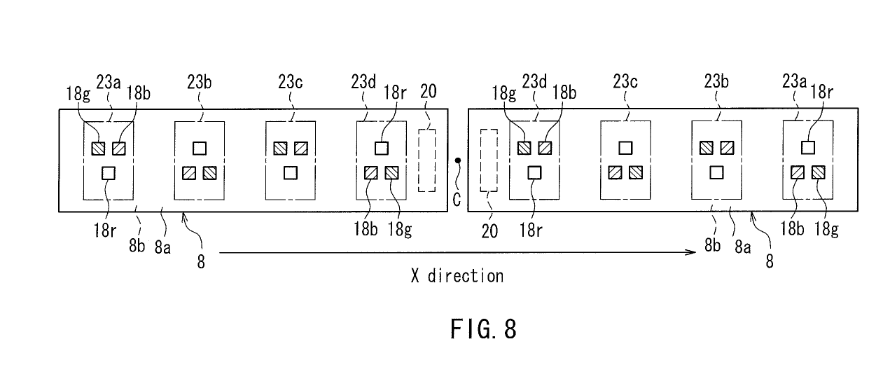

FIG. 8 is a diagram for explaining the configuration of a light emitting diode substrate in an illuminating device according to Embodiment 4 of the present invention. In FIG. 8, this embodiment mainly differs from Embodiment 2 in that the RGB light emitting diodes included in the light emitting diode units are mounted in a triangular shape on each of the LED substrates. The same components as those in Embodiment 2 are denoted by the same reference numerals, and the explanation will not repeated.

As shown in FIG. 8, each of the light emitting diode substrates (LED substrates) 8 of this embodiment includes four light emitting diode units 23a, 23b, 23c, and 23d. Each of the light emitting diode units 23a to 23d includes the RGB light emitting diodes 18.

In the illuminating device 4 of this embodiment, as shown in FIG. 8, two LED substrates 8 are adjacent in the X direction, and the RGB light emitting diodes 18 included in the light emitting diode units 23a to 23d in each of the two adjacent LED substrates 8 are provided so as to be symmetrical with respect to a point C that is in the center of these two LED substrates 8.

In the LED substrate 8 on the left side of FIG. 8, in the light emitting diode unit 23a, the light emitting diode 18r is placed at the position of one vertex of the triangular shape, and the light emitting diodes 18b, 18g are placed at the positions of the other two vertices of the triangular shape on the upper side of FIG. 8 with respect to the light emitting diode 18r. In the light emitting diode unit 23b, the light emitting diode 18r is placed at the position of one vertex of the triangular shape, and the light emitting diodes 18b, 18g are placed at the positions of the other two vertices of the triangular shape on the lower side of FIG. 8 with respect to the light emitting diode 18r. In the light emitting diode unit 23c, the light emitting diode 18r is placed at the position of one vertex of the triangular shape, and the light emitting diodes 18b, 18g are placed at the positions of the other two vertices of the triangular shape on the upper side of FIG. 8 with respect to the light emitting diode 18r. In the light emitting diode unit 23d, the light emitting diode 18r is placed at the position of one vertex of the triangular shape, and the light emitting diodes 18b, 18g are placed at the positions of the other two vertices of the triangular shape on the lower side of FIG. 8 with respect to the light emitting diode 18r.

On the other hand, in the LED substrate 8 on the right side of FIG. 8, in the light emitting diode unit 23d, the light emitting diode 18r is placed at the position of one vertex of the triangular shape, and the light emitting diodes 18b, 18g are placed at the positions of the other two vertices of the triangular shape on the upper side of FIG. 8 with respect to the light emitting diode 18r. In the light emitting diode unit 23c, the light emitting diode 18r is placed at the position of one vertex of the triangular shape, and the light emitting diodes 18b, 18g are placed at the positions of the other two vertices of the triangular shape on the lower side of FIG. 8 with respect to the light emitting diode 18r. In the light emitting diode unit 23b, the light emitting diode 18r is placed at the position of one vertex of the triangular shape, and the light emitting diodes 18b, 18g are placed at the positions of the other two vertices of the triangular shape on the upper side of FIG. 8 with respect to the light emitting diode 18r. In the light emitting diode unit 23a, the light emitting diode 18r is placed at the position of one vertex of the triangular shape, and the light emitting diodes 18b, 18g are placed at the positions of the other two vertices of the triangular shape on the lower side of FIG. 8 with respect to the light emitting diode 18r.

In each of the LED substrates 8 on the left side and right side of FIG. 8, the connector 20 is electrically connected to the electric wire H.

In other words, similarly to Embodiment 2, all the eight LED substrates 8 used in the illuminating device 4 of this embodiment have the same configuration and are housed in the case 7a of the chassis 7 while two adjacent LED substrates 8 in the X direction are rotated at 180 degrees.

With the above configuration, this embodiment can have the same function and effect as those of Embodiment 2.

### Embodiment 5

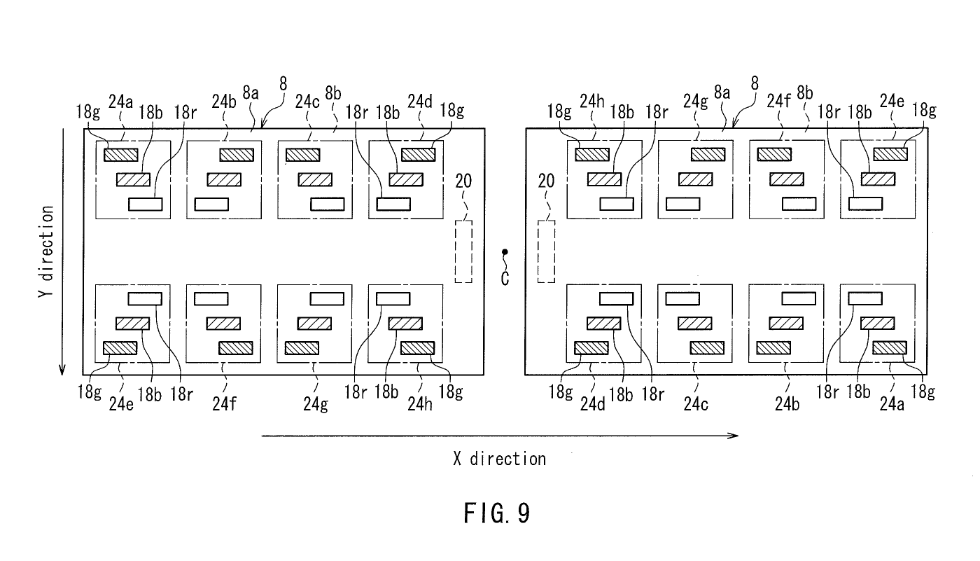

FIG. 9 is a diagram for explaining the configuration of a light emitting diode substrate in an illuminating device according to Embodiment 5 of the present invention. In FIG. 9, this embodiment mainly differs from Embodiment 1 in that the RGB light emitting diodes included in the light emitting diode units are mounted diagonally with respect to the Y direction on each of the LED substrates. The same components as those in Embodiment 1 are denoted by the same reference numerals, and the explanation will not repeated.

As shown in FIG. 9, each of the light emitting diode substrates (LED substrates) 8 of this embodiment includes eight light emitting diode units 24a, 24b, 24c, 24d, 24e, 24f, 24g, and 24h. Each of the light emitting diode units 24a to 24h includes the RGB light emitting diodes 18.

In the illuminating device 4 of this embodiment, as shown in FIG. 9, two LED substrates 8 are adjacent in the X direction, and the RGB light emitting diodes 18 included in the light emitting diode units 24a to 24h in each of the two adjacent LED substrates 8 are provided so as to be symmetrical with respect to a point C that is in the center of these two LED substrates 8.

In the LED substrate 8 on the left side of FIG. 9, the light emitting diodes 18g, 18b, and 18r in the light emitting diode unit 24a are placed diagonally in the indicated order from upper left to lower right with respect to the Y direction. The light emitting diodes 18g, 18b, and 18r in the light emitting diode unit 24b are placed diagonally in the indicated order from upper right to lower left with respect to the Y direction. The light emitting diodes 18g, 18b, and 18r in the light emitting diode unit 24c are placed diagonally in the indicated order from upper left to lower right with respect to the Y direction. The light emitting diodes 18g, 18b, and 18r in the light emitting diode unit 24d are placed diagonally in the indicated order from upper right to lower left with respect to the Y direction.

Moreover, in this left LED substrate 8, the light emitting diodes 18r, 18b, and 18g in the light emitting diode unit 24e are placed diagonally in the indicated order from upper right to lower left with respect to the Y direction. The light emitting diodes 18r, 18b, and 18g in the light emitting diode unit 24f are placed diagonally in the indicated order from upper left to lower right with respect to the Y direction. The light emitting diodes 18r, 18b, and 18g in the light emitting diode unit 24g are placed diagonally in the indicated order from upper right to lower left with respect to the Y direction. The light emitting diodes 18r, 18b, and 18g in the light emitting diode unit 24h are placed diagonally in the indicated order from upper left to lower right with respect to the Y direction.

On the other hand, in the LED substrate 8 on the right side of FIG. 9, the light emitting diodes 18g, 18b, and 18r in the light emitting diode unit 24h are placed diagonally in the indicated order from upper left to lower right with respect to the Y direction. The light emitting diodes 18g, 18b, and 18r in the light emitting diode unit 24g are placed diagonally in the indicated order from upper right to lower left with respect to the Y direction. The light emitting diodes 18g, 18b, and 18r in the light emitting diode unit 24f are placed diagonally in the indicated order from upper left to lower right with respect to the Y direction. The light emitting diodes 18g, 18b, and 18r in the light emitting diode unit 24e are placed diagonally in the indicated order from upper right to lower left with respect to the Y direction.

Moreover, in this right LED substrate 8, the light emitting diodes 18r, 18b, and 18g in the light emitting diode unit 24d are placed diagonally in the indicated order from upper right to lower left with respect to the Y direction. The light emitting diodes 18r, 18b, and 18g in the light emitting diode unit 24c are placed diagonally in the indicated order from upper left to lower right with respect to the Y direction. The light emitting diodes 18r, 18b, and 18g in the light emitting diode unit 24b are placed diagonally in the indicated order from upper right to lower left with respect to the Y direction. The light emitting diodes 18r, 18b, and 18g in the light emitting diode unit 24a are placed diagonally in the indicated order from upper left to lower right with respect to the Y direction.

In each of the LED substrates 8 on the left side and right side of FIG. 9, the connector 20 is electrically connected to the electric wire H.

In other words, similarly to Embodiment 1, all the eight LED substrates 8 used in the illuminating device 4 of this embodiment have the same configuration and are housed in the case 7a of the chassis 7 while two adjacent LED substrates 8 in the X direction are rotated at 180 degrees.

With the above configuration, this embodiment can have the same function and effect as those of Embodiment 1.

### Embodiment 6

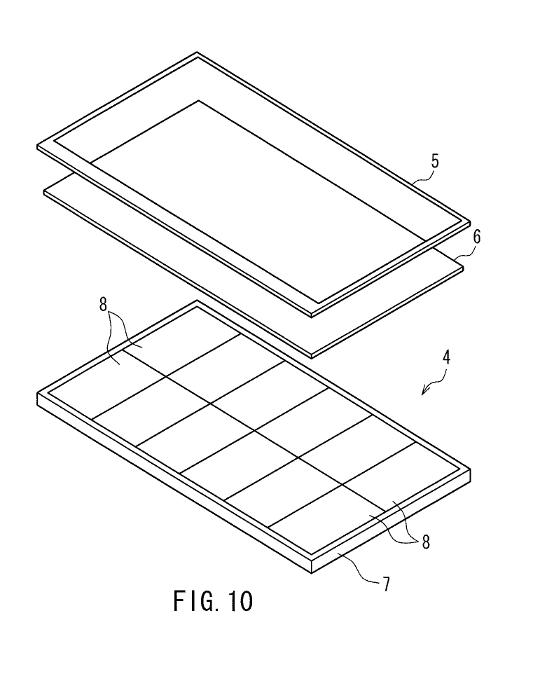

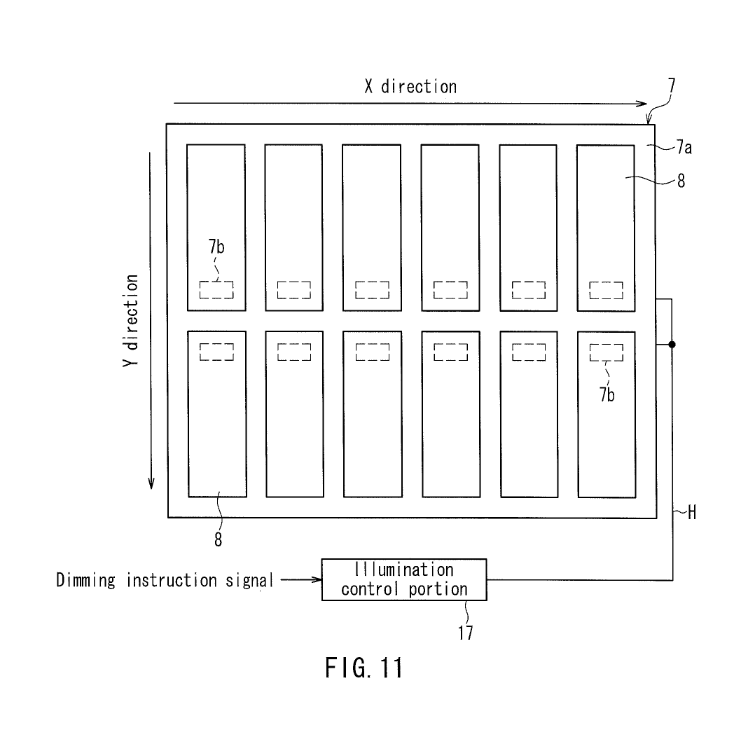

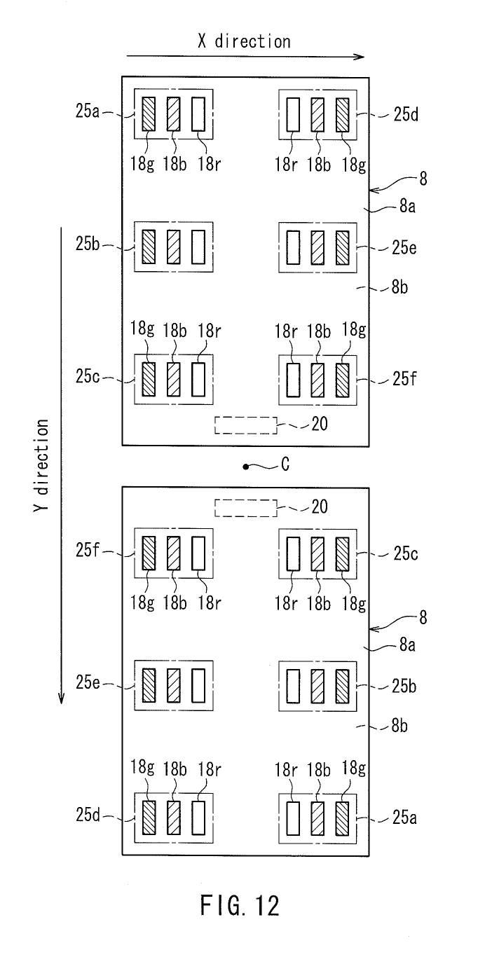

FIG. 10 is an exploded perspective view of an illuminating device according to Embodiment 6 of the present invention. FIG. 11 is a plan view showing the main configuration of the illuminating device shown in FIG. 10. FIG. 12 is diagram for explaining the configuration of a light emitting diode substrate shown in FIG. 11. In FIGS. 10, 11, and 12, this embodiment mainly differs from Embodiment 1 in that the LED substrates are housed in the case 7a of the chassis 7 with the longitudinal direction parallel to the Y direction, and that two LED substrates are adjacent in the Y direction, and the RGB light emitting diodes included in the light emitting diode units in each of the two adjacent LED substrates are provided so as to be symmetrical with respect to a point C that is in the center of these two LED substrates. The same components as those in Embodiment 1 are denoted by the same reference numerals, and the explanation will not repeated.

As shown in FIGS. 10 and 11, in the illuminating device 4 of this embodiment, a total of twelve light emitting diode substrates (LED substrates) 8 is housed in the chassis 7. Specifically, the LED substrates 8 are housed in the case 7a of the chassis 7 with the longitudinal direction parallel to the Y direction. In the case 7a, the LED substrates 8 are arranged in six columns and two rows in the X direction and the Y direction, respectively. The connectors 20 of the LED substrates 8 are electrically connected to the electric wires H that are laid through the holes 7b formed in the case 7a of the chassis 7. As shown in FIG. 11, each of two electric wires H is appropriately connected to the connectors 20 of the LED substrates 8 via six holes 7b provided along the X direction. The two electric wires H are connected to the illumination control portion 17.

As shown in FIG. 12, each of the light emitting diode substrates (LED substrates) 8 of this embodiment includes six light emitting diode units 25a, 25b, 25c, 25d, 25e, and 25f. Each of the light emitting diode units 25a to 25f includes the RGB light emitting diodes 18.

In the illuminating device 4 of this embodiment, as shown in FIG. 12, two LED substrates 8 are adjacent in the Y direction, and the RGB light emitting diodes 18 included in the light emitting diode units 25a to 25f in each of the two adjacent LED substrates 8 are provided so as to be symmetrical with respect to a point C that is in the center of these two LED substrates 8.

In the LED substrate on the upper side of FIG. 12, the light emitting diodes 18g, 18b, and 18r in each of the light emitting diode units 25a to 25c are mounted in the indicated order along the X direction on a mounting surface 8a of the LED substrate 8. Moreover, in this upper LED substrate 8, the light emitting diodes 18r, 18b, and 18g in each of the light emitting diode units 25d to 25f are mounted in the indicated order along the X direction on the mounting surface 8a of the LED substrate 8.

On the other hand, in the LED substrate 8 on the lower side of FIG. 12, the light emitting diodes 18g, 18b, and 18r in each of the light emitting diode units 25f to 25d are mounted in the indicated order along the X direction on a mounting surface 8a of the LED substrate 8. Moreover, in this lower LED substrate 8, the light emitting diodes 18r, 18b, and 18g in each of the light emitting diode units 25c to 25a are mounted in the indicated order along the X direction on the mounting surface 8a of the LED substrate 8.

In each of the LED substrates 8 on the upper side and lower side of FIG. 12, the connector 20 is electrically connected to the electric wire H.

In other words, all the twelve LED substrates 8 used in the illuminating device 4 of this embodiment have the same configuration and are housed in the case 7a of the chassis 7 while two adjacent LED substrates 8 in the Y direction are rotated at 180 degrees.

With the above configuration, this embodiment can have the same function and effect as those of Embodiment 1.

### Embodiment 7

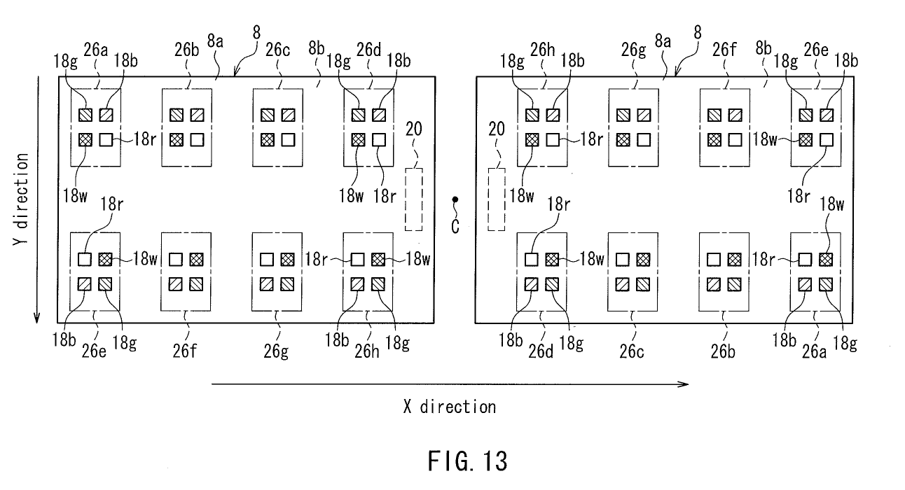

FIG. 13 is a diagram for explaining the configuration of a light emitting diode substrate in an illuminating device according to Embodiment 7 of the present invention. In FIG. 13, this embodiment mainly differs from Embodiment 1 in that each of the light emitting diode units includes a white light emitting diode that emits white light in addition to the RGB light emitting diodes. The same components as those in Embodiment 1 are denoted by the same reference numerals, and the explanation will not repeated.

As shown in FIG. 13, each of the light emitting diode substrates (LED substrates) 8 of this embodiment includes eight light emitting diode units 26a, 26b, 26c, 26d, 26e, 26f, 26g, and 26h. Each of the light emitting diode units 26a to 26h includes a white light emitting diode 18w that emits white (W) light in addition to the RGB light emitting diodes 18r, 18g, and 18b.

In the illuminating device 4 of this embodiment, as shown in FIG. 13, two LED substrates 8 are adjacent in the X direction, and the RGBW light emitting diodes 18 included in the light emitting diode units 26a to 26h in each of the two adjacent LED substrates 8 are provided so as to be symmetrical with respect to a point C that is in the center of these two LED substrates 8.

In the LED substrate 8 on the left side of FIG. 13, the RGBW light emitting diodes 18 in each of the light emitting diode units 26a to 26d are placed in the form of a square. Specifically, the light emitting diodes 18w, 18r are placed at the positions of two vertices of the square, and the light emitting diodes 18g, 18b are placed at the positions of the other two vertices of the square on the upper side of FIG. 13 with respect to the light emitting diodes 18w, 18r.

Moreover, in this left LED substrate 8, the RGBW light emitting diodes 18 in each of the light emitting diode units 26e to 26h are placed in the form of a square. Specifically, the light emitting diodes 18r, 18w are placed at the positions of two vertices of the square, and the light emitting diodes 18b, 18g are placed at the positions of the other two vertices of the square on the lower side of FIG. 13 with respect to the light emitting diodes 18r, 18w.

On the other hand, in the LED substrate 8 on the right side of FIG. 13, the RGBW light emitting diodes 18 in each of the light emitting diode units 26h to 26e are placed in the form of a square. Specifically, the light emitting diodes 18w, 18r are placed at the positions of two vertices of the square, and the light emitting diodes 18g, 18b are placed at the positions of the other two vertices of the square on the upper side of FIG. 13 with respect to the light emitting diodes 18w, 18r.

Moreover, in this right LED substrate 8, the RGBW light emitting diodes 18 in each of the light emitting diode units 26d to 26a are placed in the form of a square. Specifically, the light emitting diodes 18r, 18w are placed at the positions of two vertices of the square, and the light emitting diodes 18b, 18g are placed at the positions of the other two vertices of the square on the lower side of FIG. 13 with respect to the light emitting diodes 18r, 18w.

In each of the LED substrates 8 on the left side and right side of FIG. 13, the connector 20 is electrically connected to the electric wire H.

In other words, similarly to Embodiment 1, all the eight LED substrates 8 used in the illuminating device 4 of this embodiment have the same configuration and are housed in the case 7a of the chassis 7 while two adjacent LED substrates 8 in the X direction are rotated at 180 degrees.

With the above configuration, this embodiment can have the same function and effect as those of Embodiment 1. Moreover, this embodiment uses the RGBW light emitting diodes 18 in each of the light emitting diode units 26a to 26h, and therefore can easily provide the illuminating device 4 with high brightness.

### Embodiment 8

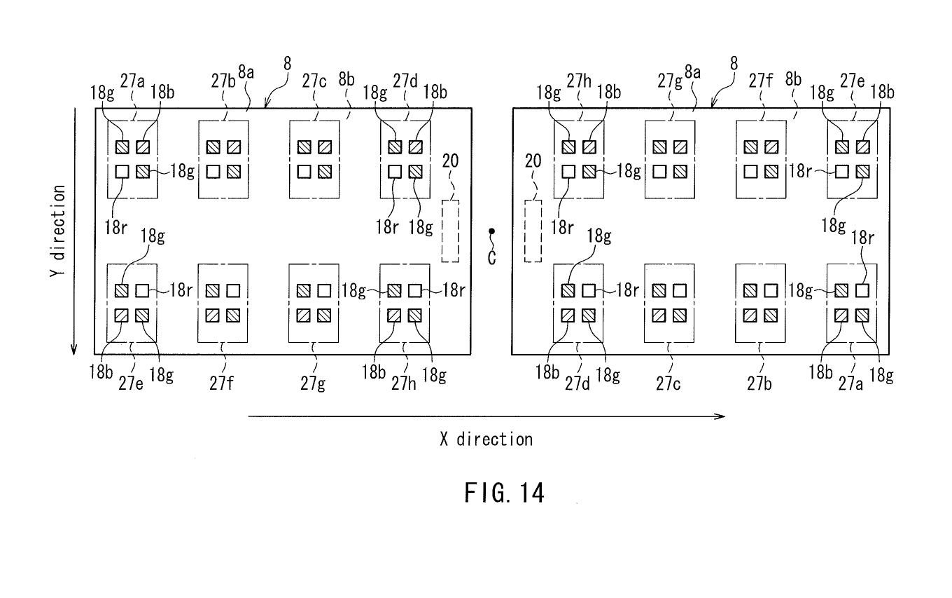

FIG. 14 is a diagram for explaining the configuration of a light emitting diode substrate in an illuminating device according to Embodiment 8 of the present invention. In FIG. 14, this embodiment mainly differs from Embodiment 1 in that each of the light emitting diode units includes a green light emitting diode in addition to each one of the RGB light emitting diodes. The same components as those in Embodiment 1 are denoted by the same reference numerals, and the explanation will not repeated.

As shown in FIG. 14, each of the light emitting diode substrates (LED substrates) 8 of this embodiment includes eight light emitting diode units 27a, 27h, 27c, 27d, 27e, 27f, 27g, and 27h. Each of the light emitting diode units 27a to 27h includes another green light emitting diode 18g that emits green (G) light in addition to the RGB light emitting diodes 18r, 18g, and 18b.

In the illuminating device 4 of this embodiment, as shown in FIG. 14, two LED substrates 8 are adjacent in the X direction, and the RGBG light emitting diodes 18 included in the light emitting diode units 27a to 27h in each of the two adjacent LED substrates 8 are provided so as to be symmetrical with respect to a point C that is in the center of these two LED substrates 8.

In the LED substrate 8 on the left side of FIG. 14, the RGBG light emitting diodes 18 in each of the light emitting diode units 27a to 27d are placed in the form of a square. Specifically, the light emitting diodes 18r, 18g are placed at the positions of two vertices of the square, and the light emitting diodes 18g, 18b are placed at the positions of the other two vertices of the square on the upper side of FIG. 14 with respect to the light emitting diodes 18r, 18g.

Moreover, in this left LED substrate 8, the RGBG light emitting diodes 18 in each of the light emitting diode units 27e to 27h are placed in the form of a square. Specifically, the light emitting diodes 18g, 18r are placed at the positions of two vertices of the square, and the light emitting diodes 18b, 18g are placed at the positions of the other two vertices of the square on the lower side of FIG. 14 with respect to the light emitting diodes 18g, 18r.

On the other hand, in the LED substrate 8 on the right side of FIG. 14, the RGBG light emitting diodes 18 in each of the light emitting diode units 27h to 27e are placed in the form of a square. Specifically, the light emitting diodes 18r, 18g are placed at the positions of two vertices of the square, and the light emitting diodes 18g, 18b are placed at the positions of the other two vertices of the square on the upper side of FIG. 14 with respect to the light emitting diodes 18r, 18g.

Moreover, in this right LED substrate 8, the RGBG light emitting diodes 18 in each of the light emitting diode units 27d to 27a are placed in the form of a square. Specifically, the light emitting diodes 18g, 18r are placed at the positions of two vertices of the square, and the light emitting diodes 18b, 18g are placed at the positions of the other two vertices of the square on the lower side of FIG. 14 with respect to the light emitting diodes 18g, 18r.

In each of the LED substrates 8 on the left side and right side of FIG. 14, the connector 20 is electrically connected to the electric wire H.

In other words, similarly to Embodiment 1, all the eight LED substrates 8 used in the illuminating device 4 of this embodiment have the same configuration and are housed in the case 7a of the chassis 7 while two adjacent LED substrates 8 in the X direction are rotated at 180 degrees.

With the above configuration, this embodiment can have the same function and effect as those of Embodiment 1. Moreover, this embodiment uses the RGBG light emitting diodes 18 in each of the light emitting diode units 27a to 27h, and therefore can easily provide the illuminating device 4 with high brightness and excellent light emission quality.

Other than the above description, e.g., RRGGB light emitting diodes including two red light emitting diodes and two green light emitting diodes may be used in a light emitting diode unit.

It should be noted that the above embodiments are all illustrative and not restrictive. The technological scope of the present invention is defined by the appended claims, and all changes that come within the range of equivalency of the claims are intended to be embraced therein.

In the above description, the present invention is applied, e.g., to the transmission type liquid crystal display device. However, the illuminating device of the present invention is not limited thereto, and may be applied to various display devices including a non-luminous display portion that utilizes light from a light source to display information such as images and characters. Moreover, the illuminating device of the present invention also may be applied to a light source. Specifically, the illuminating device of the present invention can be suitably used in a semi-transmission type liquid crystal display device or a general illuminating device such as indoor lighting.

In the above description, the connector is provided on the back surface of the light emitting diode substrate (LED substrate) and located at the predetermined position on one end in the longitudinal direction of the light emitting diode substrate. However, the light emitting diode substrate of the present invention is not limited thereto, as long as the connector is provided at a predetermined position to supply electric power to the light emitting diodes mounted on the light emitting diode substrate. Thus, the connector may be provided on the mounting surface of the light emitting diode substrate or on one end in the short-side direction of the light emitting diode substrate.

In the above description, the light emitting diode substrates are arranged in two columns and four rows in the X direction and the Y direction, respectively, or the light emitting diode substrates are arranged in six columns and two rows in the X direction and the Y direction, respectively. However, in the present invention, the number of light emitting diode substrates to be placed, the placement of the light emitting diode substrates, etc. are not particularly limited to the above, as long as a plurality of the light emitting diode substrates are placed along a predetermined arrangement direction, two light emitting diode substrates are adjacent in the arrangement direction, and the light emitting diodes included in the light emitting diode units in each of the two adjacent light emitting diode substrates are provided so as to be symmetrical with respect to a point that is in the center of these two light emitting diode substrates.

In the above description, a single light emitting diode substrate includes eight, six, or four light emitting diode units. However, the light emitting diode substrate of the present invention is not limited thereto, and may include at least one pair of the light emitting diode unit.

In the above description, the light emitting diode unit includes at least the RGB light emitting diodes. However, the light emitting diode unit may include a plurality of light emitting diodes that emit different colors of light that can be mixed into white light. Specifically, the light emitting diode unit may include a yellow light emitting diode and a blue light emitting diode.

As described in each of the above embodiments, the use of at least the RGB light emitting diodes is preferred because an illuminating device with excellent light emission quality and thus a display device with excellent display quality can be easily provided.

Other than the above description, the present invention also may be applied, e.g., to an illuminating device that is configured to be able to perform backlight scan drive where a plurality of light emitting diodes are allowed to emit light sequentially in accordance with the information to be displayed on a liquid crystal panel, or an illuminating device that is configured to be able to perform area active backlight drive where a plurality of illumination areas are set so as to correspond to display areas on a liquid crystal panel, and light emitting diodes are allowed to emit light in each of the illumination areas.

### INDUSTRIAL APPLICABILITY

The present invention is useful for an illuminating device that can be configured by one type of light emitting diode substrate even if the number of light emitting diodes to be mounted is increased, and a display device using the illuminating device.

### DESCRIPTION OF REFERENCE NUMERALS

1 Liquid crystal display device (display device)
3 Liquid crystal panel (display portion)
4 Illuminating device
7 Chassis
8 Light emitting diode substrate
18r Red light emitting diode
18g Green light emitting diode
18b Blue light emitting diode
18w White light emitting diode
19a, 19b, 19c, 19d, 19e, 19f, 19g, 19h; 21a, 21b, 21c, 21d; 22a, 22b, 22c, 22d, 22e, 22f, 22g, 22h; 23a, 23b, 23c, 23d; 24a, 24b, 24c, 24d, 24e, 24f, 24g, 24h; 25a, 25b, 25c, 25d, 25e, 25f, 26a, 26b, 26c, 26d, 26e, 26f, 26g, 26h; 27a, 27b, 27c, 27d, 27e, 27f,
27g, 27h Light emitting diode unit
20 Connector

1. An illuminating device comprising:
a light emitting diode unit including a plurality of light emitting diodes with colors that can be mixed into white color; and
a light emitting diode substrate including at least one pair of the light emitting diode unit,
wherein a plurality of the light emitting diode substrates are placed along a predetermined arrangement direction,
wherein each of the plurality of the light emitting diode substrates has a connector at a predetermined position to supply electric power to the plurality of the light emitting diodes mounted on the light emitting diode substrate, and
wherein in the plurality of the light emitting diode substrates, two light emitting diode substrates are adjacent in the arrangement direction, and the plurality of the light emitting diodes included in the light emitting diode unit in each of the two light emitting diode substrates are provided so as to be symmetrical with respect to a point that is in a center of the two light emitting diode substrates.

2. The illuminating device according to claim 1, wherein the light emitting diode unit includes a red light emitting diode, a green light emitting diode, and a blue light emitting diode that emit red light, green light, and blue light, respectively, as the plurality of the light emitting diodes.

3. The illuminating device according to claim 1, wherein the light emitting diode unit includes a red light emitting diode, a green light emitting diode, a blue light emitting diode, and a white light emitting diode that emit red light, green light, blue light, and white light, respectively, as the plurality of the light emitting diodes.

4. The illuminating device according to claim 1, wherein the light emitting diode unit includes a red light emitting diode, a green light emitting diode, and a blue light emitting diode that emit red light, green light, and blue light, respectively, as the plurality of the light emitting diodes, and also includes two or more light emitting diodes with a predetermined color selected from the red, green, and blue light emitting diodes.

5. A display device comprising a display portion,
wherein the display portion is irradiated with light from the illuminating device according to claim 1.
